(19) United States
(12) Patent Application Publication
(10) Pub. No.: US 2025/0358988 A1
(43) Pub. Date: Nov. 20, 2025

(54) ELECTRONIC DEVICE

(71) Applicant: VIVO MOBILE COMMUNICATION CO., LTD., Dongguan (CN)

(72) Inventors: Jifa BIAN, Dongguan (CN); Yan LIU, Dongguan (CN); Hengwei ZHAO, Dongguan (CN)

(73) Assignee: VIVO MOBILE COMMUNICATION CO., LTD., Dongguan (CN)

(21) Appl. No.: 19/286,242

(22) Filed: Jul. 31, 2025

Related U.S. Application Data
(63) Continuation of application No. PCT/CN2024/074186, filed on Jan. 26, 2024.

(30) Foreign Application Priority Data
Jan. 31, 2023 (CN) 202310070265.8

(51) Int. Cl. H05K 9/00

(52) U.S. Cl. CPC H05K 9/0054

(57) ABSTRACT

The present application discloses an electronic device. The electronic device includes: a display screen, including a display panel and a wire structure electrically connected to the display panel; a housing, where the display screen is disposed on one side of the housing, the housing is provided with a conductive portion, and a gap is formed between the housing and the display panel; a first electrostatic protection layer opposite the conductive portion, where the first electrostatic protection layer is conductive; and a dielectric layer disposed between the first electrostatic protection layer and the conductive portion, where the first electrostatic protection layer, the dielectric layer, and the conductive portion form a capacitive structure.

### CROSS-REFERENCE TO RELATED APPLICATIONS

This application is a continuation of International Application No. PCT/CN2024/074186, filed Jan. 26, 2024, which claims priority to Chinese Patent Application No. 202310070265.8, filed Jan. 31, 2023. The entire contents of each of the above-referenced applications are expressly incorporated herein by reference.

### TECHNICAL FIELD

The present application pertains to the field of communication technologies, and specifically relates to an electronic device.

### BACKGROUND

In current electronic devices, a gap typically exists between the display screen and the housing, allowing static electricity to be directly discharged through the gap to the flex cable region of the display screen, which may damage related components within a display screen through the flex cable.

### SUMMARY

The objective of embodiments of the present application is to provide an electronic device capable of reducing damage to components within the display screen caused by static electricity.

According to a first aspect, an embodiment of the present application provides an electronic device, including: a display screen including a display panel and a wire structure electrically connected to the display panel; a housing, where the display screen is disposed on one side of the housing, the housing is provided with a conductive portion, and a gap is formed between the housing and the display panel; a first electrostatic protection layer opposite the conductive portion, where the first electrostatic protection layer is conductive; and a dielectric layer disposed between the first electrostatic protection layer and the conductive portion; where the first electrostatic protection layer, the dielectric layer, and the conductive portion form a capacitive structure.

In this embodiment of the present application, the electronic device includes a display screen, a housing, a first electrostatic protection layer, and a dielectric layer, where the display screen includes a display panel and a wire structure electrically connected to the display panel, the display screen is disposed on one side of the housing, the housing is provided with a conductive portion, a gap is formed between the housing and the display panel, the first electrostatic protection layer is opposite the conductive portion and is conductive, the dielectric layer is disposed between the first electrostatic protection layer and the conductive portion, and the first electrostatic protection layer, the dielectric layer, and the conductive portion form a capacitive structure. By incorporating a capacitive structure between the housing and the electrostatic protection layer of the electronic device, the present application can effectively protect the flex cable of the display screen from static electricity while minimizing the impact of the electrostatic protection structure on antenna performance.

### BRIEF DESCRIPTION OF DRAWINGS

FIG. 1 is a schematic perspective view of an electronic device according to one embodiment of the present application;

FIG. 2 is a cross-sectional view of the electronic device taken along line H-H in FIG. 1;

FIG. 3 is a cross-sectional view of the electronic device taken along line I-I in FIG. 1;

FIG. 4 is a partial schematic perspective view of an electrostatic discharge path according to one embodiment of the present application;

FIG. 5 is a schematic diagram of an electrostatic discharge path according to one embodiment of the present application;

FIG. 6 is a schematic diagram of an electrostatic discharge path according to another embodiment of the present application;

FIG. 7 is a schematic structural diagram of a capacitive structure according to an embodiment of the present application;

FIG. 8 is a schematic structural diagram of a capacitive structure according to an embodiment of the present application;

FIG. 9 is a schematic structural diagram of a capacitive structure according to a further embodiment of the present application;

FIG. 10 is a schematic structural diagram of a capacitive structure according to a further embodiment of the present application;

FIG. 11 is a schematic structural diagram of a capacitive structure according to a further embodiment of the present application;

FIG. 12 is a schematic perspective diagram of an electronic device according to a further embodiment of the present application;

FIG. 13 is a schematic perspective diagram of an electronic device according to another embodiment of the present application;

FIG. 14 is a schematic diagram of an electronic device according to a further embodiment of the present application;

FIG. 15 is a schematic diagram of the electrostatic discharge path in FIG. 14;

FIG. 16 is a schematic diagram of current distribution at a fundamental frequency excited by a second electrostatic protection layer according to an embodiment of the present application;

FIG. 17 is a schematic diagram of current distribution at a third harmonic frequency excited by a second electrostatic protection layer according to an embodiment of the present application; and

FIG. 18 is a schematic diagram of current distribution at a fifth harmonic frequency excited by a second electrostatic protection layer according to an embodiment of the present application.

### DETAILED DESCRIPTION

The technical solutions in the embodiments of the present application will be described below with reference to the accompanying drawings in the embodiments of the present application. It is apparent that the described embodiments are only a part of the embodiments of the present application, and not all embodiments. All other embodiments obtained by a person of ordinary skill in the art based on the embodiments in the present application fall within the scope of protection of the present application.

The terms “first,” “second,” and the like in the specification and claims of the present application are used to distinguish similar objects and are not used to describe a specific order or sequence. It should be understood that the data used in this way can be interchanged under appropriate circumstances, so that the embodiments of the present application can be implemented in an order other than those illustrated or described herein, and the objects distinguished by “first,” “second,” and the like are generally of the same type and do not limit the number of objects, for example, the first object may be one or more. In addition, “and/or” in the specification and claims indicates at least one of the connected objects, and the character “/” generally indicates an “or” relationship between the associated objects.

The electronic device provided by the embodiments of the present application will be described below with reference to the accompanying drawings through specific embodiments and their application scenarios.

In an embodiment of the present application, an electronic device is provided, including: a display screen 1 including a display panel 101 and a wire structure 2 electrically connected to the display panel 101; a housing 3, where the display screen 1 is disposed on one side of the housing 3, the housing 3 is provided with a conductive portion, and a gap 4 is formed between the housing 3 and the display panel 101; a first electrostatic protection layer opposite the conductive portion, where the first electrostatic protection layer is conductive; and a dielectric layer disposed between the first electrostatic protection layer and the conductive portion; where the first electrostatic protection layer, the dielectric layer, and the conductive portion form a capacitive structure.

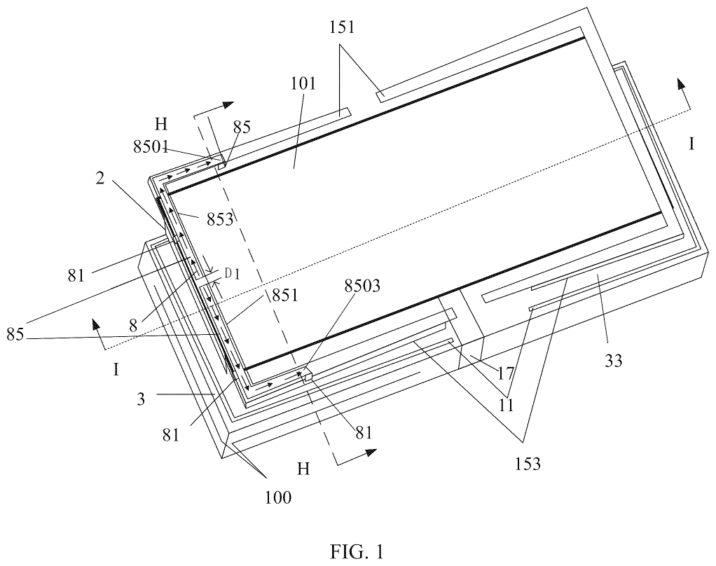

In the embodiments shown in FIG. 1 to FIG. 3, the display screen of the electronic device may be a foldable flexible display screen. The display screen includes a display panel and a wire structure electrically connected to the display panel. The wire structure includes a flex cable structure externally connected to the display panel.

The display screen 1 is disposed on one side of the housing 3, the housing 3 is provided with a conductive portion 31, and a gap 4 is formed between the housing 3 and the display panel 101. The housing includes a middle frame of the electronic device. To be specific, the housing includes a support structure configured to support and protect the display screen. The housing has a grounding path. In some embodiments, the housing is entirely made of a metal material, and the metal housing itself forms the conductive portion. The housing may also include connected plastic and conductive portions, where the conductive portion may be embedded in the plastic or disposed on the plastic surface. The conductive portion is made of a conductive material such as metal.

A gap exists between the housing and the display screen of the electronic device, and the wire structure may be exposed in the gap, affecting the appearance of the electronic device. To enhance the aesthetic appeal of the electronic device, the electronic device further includes a decorative member, which may be a decorative ring surrounding the edge of the electronic device. The decorative member is inserted into the gap to be fixed.

The first electrostatic protection layer is a conductive layer opposite the conductive portion of the housing. A dielectric layer is disposed between the first electrostatic protection layer and the conductive portion, thereby forming a capacitive structure through the first electrostatic protection layer, the dielectric layer, and the conductive portion. The first electrostatic protection layer may be directly printed on a surface of the decorative member of the electronic device using a Printing Direct Structure (PDS) process or may be an additional conductive structure disposed in the gap.

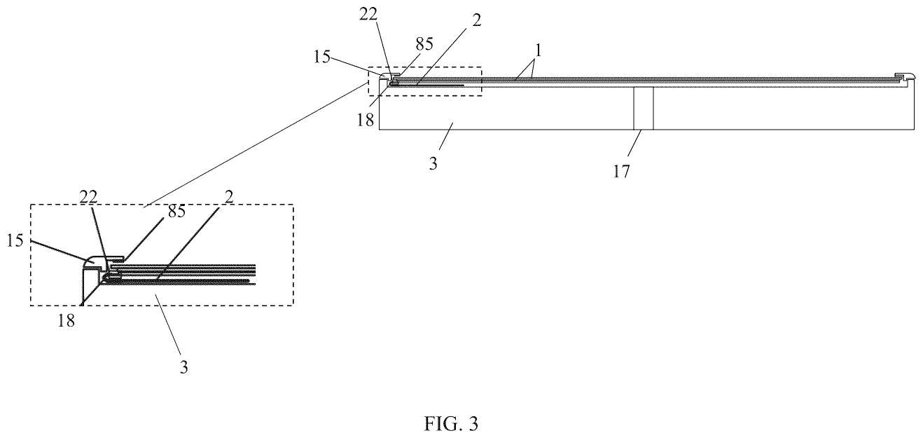

As shown in FIG. 3, at least a portion of the wire structure 2 connected to the display panel 101 is exposed in the gap 4. In the presence of static electricity, external static electricity can be discharged to ground through the first electrostatic protection layer, thereby effectively protecting the display screen from static electricity; in the absence of static electricity, the capacitive structure formed between the first electrostatic protection layer and the housing stabilizes the grounding impedance of the first electrostatic protection layer and increases the capacitance between the electrostatic protection layer and the housing, effectively reducing the impact of the electrostatic protection layer on antenna performance while achieving electrostatic protection.

In some embodiments, the first electrostatic protection layer, the dielectric layer, and the conductive portion form an electrostatic discharge path for discharging static electricity through the electrostatic discharge path including the capacitive structure. In some embodiments, static electricity breaks through the capacitive structure and is discharged to the housing through the first electrostatic protection layer, the dielectric layer, and the conductive portion in sequence, forming the electrostatic discharge path. In the embodiments, an electrostatic discharge path is directly formed by the capacitive structure to discharge static electricity, effectively preventing static electricity from entering the display panel through the exposed wire structure in the gap 4 and damaging components. Moreover, in the absence of static electricity or when static electricity is minimal, the capacitive structure formed between the first electrostatic protection layer and the housing can effectively reduce the impact of the electrostatic protection layer on antenna performance.

When the housing is entirely a metal frame, static electricity is grounded directly through the conductive portion and the grounding path formed by the metal housing itself. When the housing includes a plastic frame, static electricity is grounded through the conductive portion fixed to the plastic frame and the grounding path. The grounding path may be a wire structure embedded in the plastic frame or disposed on the surface of the plastic frame.

As shown in FIG. 1, the electronic device further includes an antenna arrangement region 100, where the electrostatic discharge path is located in the antenna arrangement region 100.

The electronic device further includes an antenna disposed at the outer edge of the electronic device to receive and transmit signals. The antenna arrangement region 100 is a region on the electronic device where the antenna is disposed.

Since the first electrostatic protection layer in the capacitive structure is a conductive layer, when the electrostatic discharge path is located in the antenna arrangement region of the electronic device, directly grounding the electrostatic protection layer to prevent static electricity may cause the electrostatic protection layer to resonate, thereby affecting the antenna performance. Therefore, grounding the electrostatic protection layer located in the antenna arrangement region 100 through the capacitive structure can effectively reduce the impact of the electrostatic protection layer on antenna performance.

The static electricity, if present, is conducted into the first electrostatic protection layer, breaks through the dielectric layer, and is conducted to the conductive portion. The static electricity is then coupled to ground through the housing and discharged via capacitive coupling. The capacitive structure formed by the first electrostatic protection layer, the dielectric layer, and the conductive portion is equivalent to connecting a capacitor with an infinite direct current impedance between the first electrostatic protection layer and the housing, stabilizing the grounding impedance of the electrostatic protection layer. This allows the addition of an electrostatic protection layer in the antenna arrangement region to prevent static electricity from damaging the display screen while minimizing the adverse impact of the added electrostatic protection layer on the antenna in the antenna arrangement region.

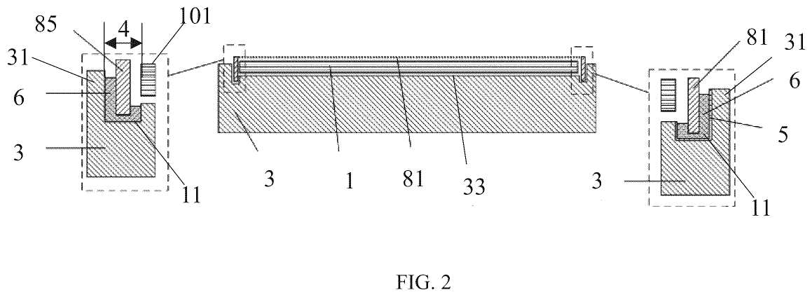

In the embodiment shown in FIG. 2, the dielectric layer includes an anodized layer 5 disposed on the housing 3, where the anodized layer 5 includes a first portion of the anodized layer disposed opposite the first electrostatic protection layer 81 and a second portion of the anodized layer offset from the first electrostatic protection layer, and a thickness of the first portion of the anodized layer is less than a thickness of the second portion of the anodized layer.

The inner side of the housing is coated with an anodized layer. The anodized layer includes two parts: a first portion of the anodized layer disposed opposite the first electrostatic protection layer and a second portion of the anodized layer offset from the first electrostatic protection layer. The second portion of the anodized layer has a greater thickness and is used for housing insulation. The first portion of the anodized layer has a smaller thickness, forming a dielectric layer that is more easily broken down by static electricity, thereby forming, together with the first electrostatic protection layer and the conductive portion, a capacitive structure configured to discharge static electricity through the electrostatic discharge path of the capacitive structure.

When the capacitive structure is used to discharge static electricity through the electrostatic discharge path, a greater thickness of the anodized layer indicates stronger insulation performance; a smaller thickness of the anodized layer indicates weaker insulation performance and a lower threshold voltage required for static electricity to break down the anodized layer. Since the thickness of the first portion of the anodized layer is less than that of the second portion of the anodized layer, when static electricity is conducted into the first electrostatic protection layer and the threshold voltage for electrostatic discharge can break down the first portion of the anodized layer of the corresponding thickness, the static electricity is conducted to the conductive portion and coupled to ground through the housing for discharge.

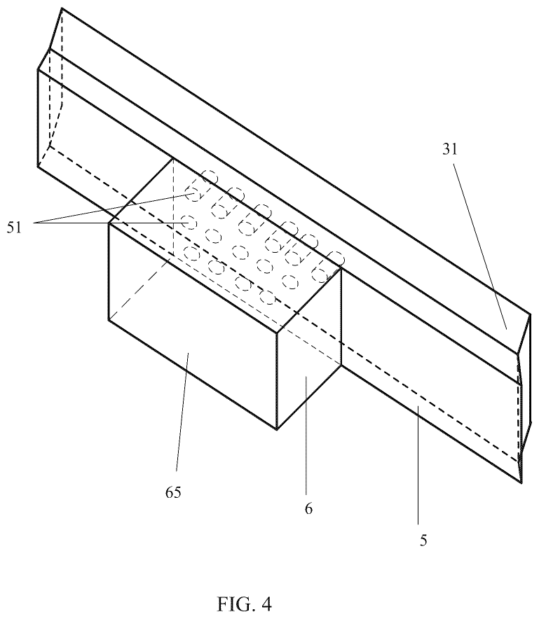

As shown in FIG. 4, the dielectric layer includes an anodized layer 5 disposed on the conductive portion 31, where the anodized layer 5 has at least one hole 51 to form the electrostatic discharge path.

In this embodiment, the dielectric layer is an anodized layer disposed between the first electrostatic protection layer and the conductive portion. As shown in FIG. 2, the conductive portion 31 is a part of the housing 3, an anodized layer 5 is disposed between the first electrostatic protection layer 81 and the conductive portion 31, and holes 51 are provided in the anodized layer 5, allowing air to pass through. Since the threshold voltage for static electricity to break down an air dielectric layer is significantly lower than that for breaking down the anodized layer 5, these holes 51 significantly reduce the threshold voltage for electrostatic discharge, greatly increasing the reliability of the electrostatic discharge path formed by the capacitive structure in protecting the display screen 1 from static electricity.

Further, the electronic device includes a conductive adhesive 6 disposed between the anodized layer and the first electrostatic protection layer 81, where the conductive adhesive 6 contains conductive particles, and a particle size of the conductive particles is larger than a diameter of the holes 51.

In conjunction with FIG. 2 and FIG. 4, a conductive adhesive 6 is added between the anodized layer 5 with holes and the first electrostatic protection layer 81. The conductive adhesive 6 essentially conducts electricity through metal particles, and the conductive particles are relatively large, with a particle size larger than the diameter of the holes 51 in the anodized layer 5, allowing air to pass through but preventing the conductive adhesive from passing through, facilitating the formation of an air layer within the holes 51.

The holes 51 are formed in the first portion of the anodized layer. The conductive adhesive 6 is filled between the first electrostatic protection layer 81 and the anodized layer 5, where a first surface 65 of the conductive adhesive 6 contacts the first electrostatic protection layer, and a second surface of the conductive adhesive 6 opposite the first surface 65 contacts the anodized layer 5 with holes 51, and the anodized layer 5 is disposed on the conductive portion 31.

The conductive adhesive 6 not only can fix the first electrostatic protection layer 81 but also can reduce the distance for electrostatic discharge, thereby lowering the threshold voltage for electrostatic discharge, allowing low-voltage static electricity, such as 1-4 kV, to be discharged toward the housing through the conductive portion, avoiding the possibility of low-voltage static electricity being discharged to the wire structure and damaging the display screen in the absence of conductive adhesive. In addition, the conductive adhesive 6 can increase the capacitance of the capacitive structure, further reducing the impact of the electrostatic protection layer on antenna performance in the absence of static electricity.

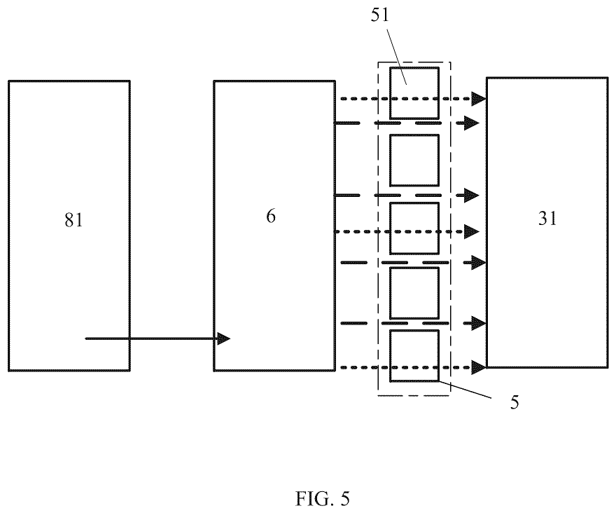

The electrostatic discharge path formed by the first electrostatic protection layer 81, the conductive adhesive 6, the anodized layer 5 with holes 51, and the conductive portion 31 is shown in FIG. 5. Static electricity is first discharged to the conductive adhesive 6 through the direct conductive electrostatic discharge path (solid arrow) corresponding to the first electrostatic protection layer 81 and the conductive adhesive 6, then discharged to the conductive portion 31 through the electrostatic coupling discharge path (dashed arrow) corresponding to the capacitive structure formed by the conductive adhesive 6, the anodized layer 5 with holes 51, and the conductive portion 31, and is grounded through the housing 3 connected to the conductive portion 31.

As shown in FIG. 6, the electronic device further includes a conductive adhesive 6, where the first electrostatic protection layer 81 is fixed to the housing through the conductive adhesive 6, and the conductive adhesive 6 is located between the dielectric layer and the first electrostatic protection layer 81. The first electrostatic protection layer, the conductive adhesive, the dielectric layer, and the conductive portion form an electrostatic discharge path.

As described above, the added conductive adhesive 6 not only fixes the first electrostatic protection layer 81 but also reduces the threshold voltage for electrostatic discharge when the capacitive structure is used as an electrostatic discharge path. In addition, the conductive adhesive 6 can increase the capacitance of the capacitive structure, further reducing the impact of the electrostatic protection layer on antenna performance in the absence of static electricity.

The electrostatic discharge path formed by the first electrostatic protection layer 81, the conductive adhesive 6, the anodized layer 5, and the conductive portion 31 is shown in FIG. 6. As can be seen from FIG. 6, static electricity is first discharged to the conductive adhesive 6 through the direct conductive electrostatic discharge path (solid arrow) corresponding to the first electrostatic protection layer 81 and the conductive adhesive 6, then discharged to the conductive portion through the electrostatic coupling discharge path (dashed arrow) corresponding to the capacitive structure formed by the conductive adhesive 6, the anodized layer 5, and the conductive portion 31, and is grounded through the housing 3 connected to the conductive portion 31.

The difference between this embodiment and the embodiment shown in FIG. 5 is that no holes 51 are provided in the anodized layer. Therefore, when the anodized layer in the embodiment of FIG. 6 has the same thickness as the anodized layer in the embodiment of FIG. 5, the threshold voltage for electrostatic discharge in the embodiment of FIG. 5 is lower than that in the embodiment of FIG. 6 due to the presence of holes in the anodized layer.

In some embodiments, the housing 3 has a bearing surface 33 configured to support the display screen 1, where the bearing surface 33 is provided with a groove 11, the groove 11 extends along an edge of the display screen 1, and the first electrostatic protection layer is inserted into the groove 11; the conductive portion and the dielectric layer are disposed opposite the first electrostatic protection layer, and the three together form the electrostatic discharge path of the capacitive structure.

Referring to FIG. 1 and FIG. 2, the bearing surface 33 of the housing 3 configured to support the display screen 1, that is, the surface of the housing parallel to the light-emitting surface of the display screen 1, is provided with a groove 11, where the groove 11 extends along an edge of the display screen 1, and the first electrostatic protection layer 81 may be inserted into the groove 11.

In the embodiments, the conductive portion 31 is a part of the housing 3. As shown in the partial enlarged view of the dashed area corresponding to FIG. 2, the first electrostatic protection layer 81 is inserted into the groovell of the housing 3, and the conductive portion 31 and the dielectric layer including the anodized layer 5 are disposed opposite the first electrostatic protection layer 81, and the three together form the electrostatic discharge path of the capacitive structure. In addition, a gap 14 is formed between the conductive portion 31 of the housing 3 and the display panel 101.

In some embodiments, the conductive portion is located at an edge of the bearing surface 33 and protrudes from the bearing surface 33, such that the conductive portion is opposite a sidewall of the display panel 101 to limit the display screen 1, and the groove 11 extends to the conductive portion.

In the embodiments, the conductive portion is a part of the housing. As shown in FIG. 2, the conductive portion 31 is located at an edge of the bearing surface 33 of the housing 3 and protrudes from the bearing surface 33, such that a conductive portion 31 is opposite the sidewall of the display panel 101 to limit the display screen 1. As shown in FIG. 2, the groove 11 extends to the conductive portion 31.

In some embodiments, the conductive portion is opposite a side of the display panel 101, the gap 4 is formed between the conductive portion and the display panel, one end of the first electrostatic protection layer is located within the gap 4, and another end of the first electrostatic protection layer extends toward the opening of the gap 4 and protrudes from the display screen 1 and/or the housing 3.

As shown in FIG. 2, the conductive portion 31 is opposite a side of the display panel 101, the gap 4 is formed between the conductive portion 31 and the display panel 101, one end of the first electrostatic protection layer 81 is located within the gap 4, and another end of the first electrostatic protection layer 81 extends toward the opening of the gap 4 and protrudes from the display screen 1 and/or the housing 3.

Thus, when a static electricity source, such as a human hand, touches the electronic device, it will first contact the first electrostatic protection layer protruding from the display screen and/or the housing, so that static electricity is preferentially discharged through the first electrostatic protection layer, effectively preventing static electricity from damaging other components.

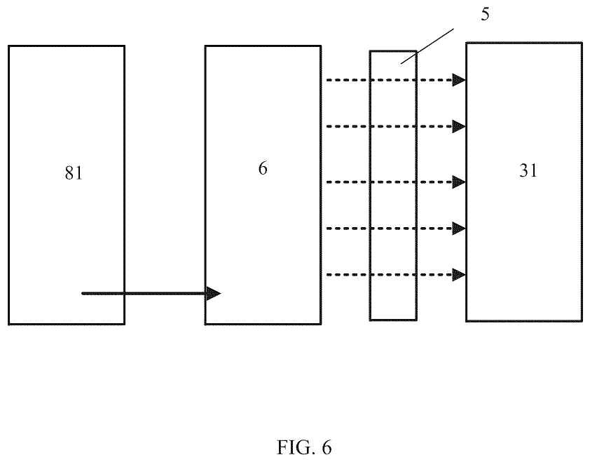

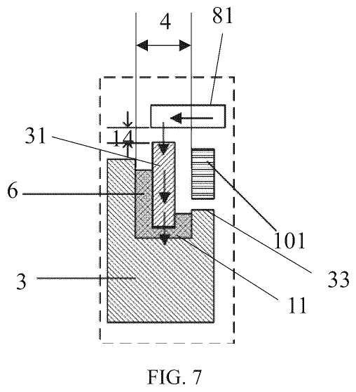

FIG. 7 is a schematic structural diagram of a capacitive structure according to an embodiment of the present application. In the embodiment shown in FIG. 7, the dielectric layer is an air layer, one side of the conductive portion 31 is fixed within the gap 4, and another side of the conductive portion 31 extends toward the opening of the gap 4; the first electrostatic protection layer 81 is stacked directly above the conductive portion 31 and separated from the conductive portion 31 to form a spacing 14 to accommodate the dielectric layer.

In conjunction with FIG. 7, the conductive portion 31 is fixed to the housing 3. In this embodiment, the conductive portion 31 is attached to the housing 3 via a conductive adhesive 6. In some embodiments, one side of the conductive portion 31 is fixed within the gap 4 formed between the housing 3 and the display panel 101, and another side of the conductive portion 31 extends toward the opening of the gap 4. The first electrostatic protection layer 81 is stacked directly above the conductive portion 31 and separated from the conductive portion 31 to form a spacing 14. This spacing 14 forms an air dielectric layer. Thus, the conductive portion 31, the air layer, and the first electrostatic protection layer 81 form a parallel plate equivalent capacitive structure, and the electrostatic discharge path corresponding to this capacitive structure is shown by the arrow in FIG. 8.

When static electricity on the electronic device is coupled to ground through the capacitive structure formed by the first electrostatic protection layer 81 and the spaced conductive portion 31, the static electricity is directly discharged through the first electrostatic protection layer 81, breaks down the air layer in the spacing 14, discharges the static electricity to the conductive portion 31 via electrostatic coupling, and is then conducted to the housing 3 via the conductive portion 31 and the conductive adhesive 6.

When static electricity on the electronic device is not coupled to ground through the capacitive structure formed by the first electrostatic protection layer 81 and the spaced conductive portion 31, the direct current impedance of the capacitive structure formed between the first electrostatic protection layer 81 and the conductive portion 31 fixed to the housing 3 is nearly infinite, effectively reducing the impact on antenna performance.

Further, the housing 3 is provided with a groove 11, where the groove 11 extends around the display screen 1, the conductive portion is fixed to the groove 11 via a conductive adhesive, an end face of the conductive portion 31 facing away from the groove 11 and the first electrostatic protection layer 81 are disposed opposite each other and form the spacing 14, and the first electrostatic protection layer 81 is disposed on the display side of the display panel 101.

Referring to FIG. 1, the housing 3 is provided with a groove 11 extending along the edge of the display screen, the conductive portion 31 may be fixed to the groove 11 via the conductive adhesive 6, the conductive portion 31 may be formed at a corresponding position inside the decorative member using a printing direct structure process, and the first electrostatic protection layer 81 may also be formed at a corresponding position inside the decorative member using a printing direct structure process.

As shown in FIG. 7, the end face of the conductive portion 31 facing away from the groove 11 and the first electrostatic protection layer 81 are disposed opposite each other and form the spacing 14 in the form of an air layer.

As described above, the conductive portion 31 and the first electrostatic protection layer 81 form a capacitive structure through the spacing 14 in the form of an air layer, and the shapes of the spacing 14 formed vary depending on the different end face structures of the conductive portion 31 disposed opposite the first electrostatic protection layer 81.

In the embodiment shown in FIG. 8, the end face of the conductive portion 31 facing away from the groove 11 and disposed opposite the first electrostatic protection layer 81 is planar, a side of the first electrostatic protection layer 81 disposed opposite the conductive portion 31 is also planar, and a parallel planar capacitor is formed between them.

In some embodiments, the end face of the conductive portion 31 facing away from the groove 11 and the first electrostatic protection layer 81 are disposed opposite each other and form the spacing 14, where the end face of the conductive portion 31 facing away from the groove 11 has a first protrusion structure 931, and a second protrusion structure 831, matching the first protrusion structure 931, is further provided on a side of the first electrostatic protection layer facing the conductive portion; and the first protrusion structure 931, the second protrusion structure 831, and the dielectric layer located between the first protrusion structure 931 and the second protrusion structure 831 form the electrostatic discharge path.

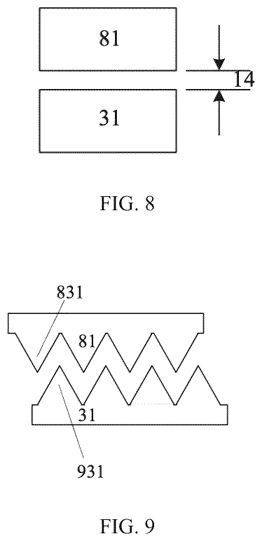

In the embodiment shown in FIG. 9, the end face of the conductive portion 31 facing away from the groove 11 is provided with a serrated first protrusion structure 931, and correspondingly, the first electrostatic protection layer 81, which is disposed opposite and close to the conductive portion 31, is also provided with an identical serrated second protrusion structure 831.

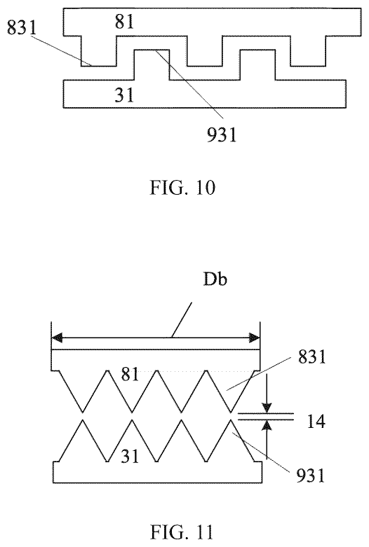

In the embodiment shown in FIG. 10, the end face of the conductive portion 31 facing away from the groove 11 is provided with a block-shaped first protrusion structure 931. The first electrostatic protection layer 81, which is disposed opposite and close to the conductive portion 31, is also provided with an identical block-shaped second protrusion structure 831, and the protruding portion of the first protrusion structure 931 of the conductive portion 31 is offset from the protruding portion of the second protrusion structure 831 of the first electrostatic protection layer 81. The difference between this embodiment and the embodiment shown in FIG. 9 is that the end face of the first protrusion structure 931 is planar, that is, the first protrusion structure 931 is a rectangular block-shaped structure.

In the embodiment shown in FIG. 11, the serrated first protrusion structure 931 of the conductive portion 31 and the serrated second protrusion structure 831 of the first electrostatic protection layer 81 have their serrated tips disposed opposite each other, whereas in the embodiment of FIG. 9, the serrated first protrusion structure 931 of the conductive portion 31 and the serrated second protrusion structure 831 of the first electrostatic protection layer 81 have their serrated tips parallel and offset.

In some embodiments, the minimum distance of the spacing 14 is less than 0.3 millimeters.

The provision of an air layer spacing 14 of less than 0.3 millimeters between the first electrostatic protection layer 81 disposed on the display side of the display panel 101 and the conductive portion 31 connected to the housing 3 can ensure the reliability of the electrostatic protection function of the display panel.

In addition, for a conductive portion disposed in the antenna arrangement region, a larger width Db of the conductive portion indicates a lower corresponding resistance, making the conductive portion less prone to passivation during electrostatic discharge and extending its lifespan. However, an excessive width would reduce the antenna clearance, affecting antenna performance.

As shown in FIG. 7, the housing 3 has a bearing surface 33 configured to support the display screen 1, the first electrostatic protection layer 81 extends in a direction parallel to the bearing surface 33, and the conductive portion 31 extends in a direction perpendicular to the bearing surface 33.

In conjunction with FIG. 1 and FIG. 7, the housing 3 carries the display screen, the first electrostatic protection layer 81 extends in a direction parallel to the bearing surface 33, that is, parallel to the display side of the display panel 101, and the first electrostatic protection layer 81 may be directly printed at a corresponding position on a decorative member protecting the display screen using a printing direct structure process, where the position is parallel to the display side of the display panel 101. The conductive portion 31 may be formed at a corresponding position inside the decorative member using a printing direct structure process, where the position is perpendicular to the display side of the display panel 101, that is, perpendicular to the bearing surface 33 of the housing 3.

Referring to FIG. 7, the conductive portion 31 extends in a direction perpendicular to the bearing surface 33 of the housing 3 and is separated and spaced from the first electrostatic protection layer 81, forming a capacitive structure for electrostatic discharge through the air layer corresponding to the spacing 14.

The electronic device further includes a decorative member 15 as shown in the figure, where the decorative member 15 has a first decorative portion 151 stacked on a display side of the display screen 1 and a second decorative portion 153 inserted into the gap 4, the first decorative portion 151 and the second decorative portion 153 being connected; and the first electrostatic protection layer 81 is disposed on the first decorative portion 151, and the conductive portion 31 is disposed on the second decorative portion 153.

In conjunction with FIG. 1, in this embodiment, the first decorative portion 151 of the decorative member 15 is stacked on the display side of the display screen, the second decorative portion 153 of the decorative member 15 is fixed to the housing 3 through the groove 11 on the housing 3, and the first decorative portion 151 and the second decorative portion 153 are connected as a single unit. The first electrostatic protection layer 81 is formed on the inner side of the first decorative portion 151 using a printing direct structure process and is opposite the display side of the display screen. The conductive portion 31 is formed on the inner side of the second decorative portion 153 using a printing direct structure process and forms a corresponding air layer spacing 14 with the first electrostatic protection layer 81 on the first decorative portion 151.

In some embodiments, the electronic device further includes a second electrostatic protection layer 85, where the second electrostatic protection layer 85 is connected to the first electrostatic protection layer and extends to a display side of the display panel 101; and the housing 3 has a grounding path, and the second electrostatic protection layer 85 is in direct contact with the housing 3 for grounding.

As shown in FIG. 1, the second electrostatic protection layer 85 is a conductive layer stacked on the display side of the display panel 101, and the second electrostatic protection layer 85 is connected to the first electrostatic protection layer 81 at multiple positions.

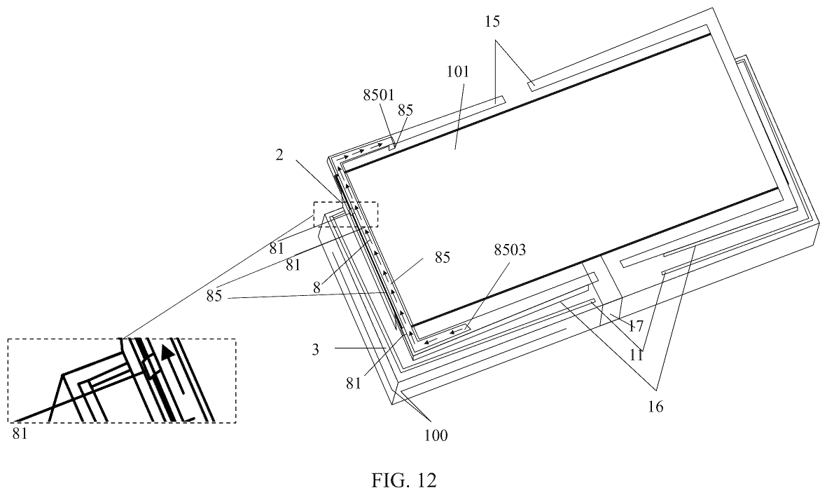

In the embodiment shown in FIG. 12, the second electrostatic protection layer 85 is a conductive layer stacked on the display side of the display panel 101, and the second electrostatic protection layer 85 is connected to the first electrostatic protection layer 81 at multiple positions.

In the embodiment shown in FIG. 1, the second electrostatic protection layer 85 includes multiple segmented conductive layers, and the second electrostatic protection layer 85 has segments entirely located within the antenna arrangement region 100. In the embodiment shown in FIG. 12, the second electrostatic protection layer 85 is a continuously extending conductive layer, that is, the grounding point of the second electrostatic protection layer 85 is located outside the antenna arrangement region 100.

Since the grounding point of the second electrostatic protection layer 85 located outside the antenna arrangement region 100 has a minimal impact on antenna performance, the grounding point of the second electrostatic protection layer 85 located outside the antenna arrangement region 100 may be in direct contact with the housing 3 for grounding. As shown in FIG. 12, the end 8501 of the second electrostatic protection layer 85 located outside the antenna arrangement region 100 is a grounding point, and the second electrostatic protection layer 85 at this grounding point is in direct contact with the housing 3 for electrical connection and grounding. In some embodiments, the second electrostatic protection layer 85 may extend into the groove 11 at this grounding point, that is, the second electrostatic protection layer 85 extends into the gap between the display panel and the housing to facilitate direct contact and conduction with the housing.

In the embodiment shown in FIG. 1, the second electrostatic protection layer 85 has segments entirely located within the antenna arrangement region 100, and the grounding points of these segments are inevitably located within the antenna arrangement region 100. To reduce the impact of these segments on antenna performance, the second electrostatic protection layer 85 of these segments should be grounded through an electrostatic discharge path including the capacitive structure as described above.

In some embodiments, the second electrostatic protection layer 85 is connected to the first electrostatic protection layer and extends to a display side of the display panel 101, the first electrostatic protection layer is disposed in the gap 4 between the housing 3 and the display panel 101, and the second electrostatic protection layer 85 is grounded through the electrostatic discharge path.

In this embodiment shown in FIG. 1 and FIG. 2, an end 8503 of the second electrostatic protection layer 85 located within the antenna arrangement region 100 is connected to the first electrostatic protection layer 81 forming the electrostatic discharge path for grounding and extends to a display side of the display panel 101, and the first electrostatic protection layer 81 is disposed in the gap 4 between the housing 3 and the display panel 101. Thus, static electricity can be directly discharged to the second electrostatic protection layer 85, and then the static electricity on the second electrostatic protection layer 85 is discharged to the housing 3 via electrostatic coupling through a capacitive structure formed by the first electrostatic protection layer 81, the dielectric layer including the anodized layer 5, and the conductive portion 31.

The dielectric layer here may also be an air layer as described in the previous embodiments, and details are not to be repeated here.

Further, the second electrostatic protection layer 85 extends around an edge of an end of the display panel 101 near the wire structure 2, and the first electrostatic protection layer is disposed at an end of the second electrostatic protection layer 85 far away from the wire structure 2 to form a grounding connection point.

As shown in FIG. 3, the wire structure 2 is located between the housing 3 and the display panel of the display screen 1 and is exposed through the gap. The second electrostatic protection layer 85 extends around an edge of an end of the display panel 101 near the flex cable to prevent static electricity from entering the display screen through the flex cable and damaging related components.

In some embodiments, an orthographic projection of the second electrostatic protection layer 85 on the plane of the display panel completely covers the gap 4. Orthographic projections of the end 8501 and the end 8503 far away from the end 8501 of the second electrostatic protection layer 85 on a plane of the display panel are respectively located on opposite sides of an orthographic projection of the wire structure 2 on the plane of the display panel, ensuring that the second electrostatic protection layer 85 can fully surround the wire structure to effectively prevent static electricity from being discharged to the wire structure.

Further, the electronic device includes a decorative member 15, where the decorative member 15 has a first decorative portion 151 stacked on the display side of the display screen and a second decorative portion 153 inserted into the gap 4, the first decorative portion 151 and the second decorative portion 153 being connected; and the first electrostatic protection layer is disposed on the second decorative portion, and the second electrostatic protection layer 85 is disposed on the first decorative portion.

As shown in FIG. 1, the first decorative portion 151 of the decorative member 15 is stacked on the display side of the display screen 1, the second decorative portion 153 of the decorative member 15 is fixed to the housing 3 through the groove 11 on the housing 3, and the first decorative portion 151 and the second decorative portion 153 are connected as a single unit. In this embodiment, the second electrostatic protection layer 81 may be formed on the inner side of the first decorative portion 153 using a printing direct structure process and is opposite the display side of the display screen 1. The first electrostatic protection layer 81 may be formed on the inner side of the second decorative portion 153 using a printing direct structure process.

In some embodiments, the electronic device further includes an antenna arrangement region 100; the second electrostatic protection layer 85 includes a first electrostatic protection segment 851 and a second electrostatic protection segment 853, where the first electrostatic protection segment 851 and the second electrostatic protection segment 853 are separated and spaced apart. The first electrostatic protection segment 851 has a first grounding connection point located within the antenna arrangement region 100. The second electrostatic protection segment 853 has a second grounding connection point located outside the antenna arrangement region 100. The first electrostatic protection layer is connected to the first grounding connection point of the first electrostatic protection segment 851, and the first grounding connection point is grounded through the electrostatic discharge path. The second grounding connection point of the second electrostatic protection segment 853 is in direct contact with the housing 3 for conduction and is grounded through a grounding path of the housing.

In this embodiment, as shown in FIG. 1, the second electrostatic protection layer 85 extending on the display side of the display screen 1 is divided into a first electrostatic protection segment 851 and a second electrostatic protection segment 853, where the first electrostatic protection segment 851 and the second electrostatic protection segment 853 are spaced apart by a distance, forming a gap D1. The first electrostatic protection segment 851 is connected to the first electrostatic protection layer 81 at a corresponding grounding connection point, and is configured to discharge static electricity 8 to the housing 3 through the first electrostatic protection layer 81 disposed at the grounding connection point.

As shown in FIG. 1, the first grounding connection point on the first electrostatic protection segment 851 is located within the antenna arrangement region 100, the first electrostatic protection layer 81 is connected to the first grounding connection point of the first electrostatic protection segment 851, and the first grounding connection point of the first electrostatic protection segment 851 is grounded through the electrostatic discharge path. This allows the grounding connection point located within the antenna arrangement region 100 to be grounded through an electrostatic discharge path including a capacitive structure, achieving electrostatic coupling discharge, which meets electrostatic protection requirements while minimizing the impact on the antenna.

The second grounding connection point on the second electrostatic protection segment 853 is located outside the antenna arrangement region 100, the end 8501 of the second electrostatic protection segment 853 located outside the antenna arrangement region 100 is the second grounding connection point, and the second electrostatic protection layer 85 at the second grounding connection point is in direct contact with the housing 3 for electrical connection and grounding, achieving direct electrostatic direct current discharge.

The second grounding connection point disposed at the end 8501 of the second electrostatic protection segment 853 is located outside the antenna arrangement region 100, far away from the antenna of the electronic device. Therefore, the discharge of static electricity to ground through the second grounding connection point has little impact on the antenna performance, and it is thus unnecessary to provide the capacitive structure as described above.

It should be noted that the second electrostatic protection layer herein includes the first electrostatic protection segment and the second electrostatic protection segment, and is not limited to only two electrostatic protection segments; depending on the antenna scheme and/or folding state of different electronic devices, it may be divided into three or more electrostatic protection segments. Depending on whether the position of the grounding connection point connected to the first electrostatic protection layer is within the antenna arrangement region 100, the static electricity on the second electrostatic protection layer may be discharged through capacitive coupling or direct conductive paths.

In some embodiments, the first electrostatic protection segment 851 and the second electrostatic protection segment 853 are separated to form a gap D1, where the gap D1 is opposite the wire structure 285; and a minimum distance between a plane of the second electrostatic protection layer and the wire structure 2 is greater than or equal to twice a width of the gap D1.

The gap D1 formed by the separation between adjacent two electrostatic protection segments after the second electrostatic protection layer 85 is segmented is opposite the wire structure 2. The size of the gap D1 should not be too large; if the gap D1 is too large, static electricity will preferentially pass through the gap D1 to the opposite wire structure 2, damaging the wire structure 2. Therefore, a minimum distance between a plane of the second electrostatic protection layer 85 and the wire structure 2 needs to be greater than or equal to twice a width of the gap D1. Thus, when static electricity is present in the electronic device, the static electricity will preferentially be discharged through the second electrostatic protection layer 85 and the corresponding connected first electrostatic protection layer 81 via the electrostatic discharge path.

In some embodiments, the second electrostatic protection layer 85 is connected to multiple first electrostatic protection layers so as to be grounded through multiple electrostatic discharge paths.

In this embodiment, as shown in FIG. 1 and FIG. 2, the second electrostatic protection layer 85 is connected to the first electrostatic protection layer 81 and extends to a display side of the display panel 101, multiple first electrostatic protection layers 81 are respectively disposed in the gap 4 between the housing 3 and the display panel 101, and the second electrostatic protection layer 85 is connected to multiple first electrostatic protection layers 81 to form a capacitive structure, thereby being grounded through multiple electrostatic discharge paths of the capacitive structure.

Further, the electronic device includes an antenna arrangement region 100; the second electrostatic protection layer 85 includes a first electrostatic protection segment 835 and a second electrostatic protection segment 836 located within the antenna arrangement region 100, where the first electrostatic protection segment 835 and the second electrostatic protection segment 836 are separated and spaced apart, the first electrostatic protection segment 835 has a first grounding connection point, and the second electrostatic protection segment 836 has a second grounding connection point; and the first grounding connection point of the first electrostatic protection segment 835 is connected to one of the first electrostatic protection layers, causing the first electrostatic protection segment 835 to be grounded through a first electrostatic discharge path; and the second grounding connection point of the second electrostatic protection segment 836 is connected to another of the first electrostatic protection layers, causing the second electrostatic protection segment 836 to be grounded through a second electrostatic discharge path.

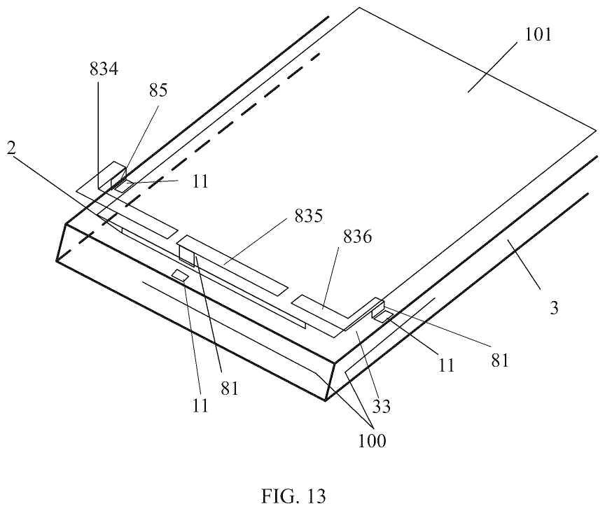

Referring to the embodiment shown in FIG. 13, the second electrostatic protection layer 85 includes a first electrostatic protection segment 835, a second electrostatic protection segment 836, and a third electrostatic protection segment 834. The first electrostatic protection segment 835 and the second electrostatic protection segment 836 are located within the antenna arrangement region 100. The third electrostatic protection segment 834 is disposed outside the antenna arrangement region 100. The first electrostatic protection segment 835 and the second electrostatic protection segment 836 are separated and spaced apart, and the first electrostatic protection segment 835 and the second electrostatic protection segment 836 each have grounding connection points. The first grounding connection point of the first electrostatic protection segment 835 is connected to a first electrostatic protection layer 81, causing the first electrostatic protection segment 835 to be grounded through a first electrostatic discharge path; and the second grounding connection point of the second electrostatic protection segment 836 is connected to another first electrostatic protection layer 81, causing the second electrostatic protection segment 836 to be grounded through a second electrostatic discharge path. The first electrostatic protection segment 835 and the second electrostatic protection segment 836 are each connected to a first electrostatic protection layer 81, allowing the static electricity thereon to be discharged through an electrostatic discharge path including a capacitive structure, achieving electrostatic coupling discharge, which meets electrostatic protection requirements while minimizing the impact on the antenna.

The end of the third electrostatic protection segment 834 is a grounding point, and the second electrostatic protection layer 85 at this grounding point is in direct contact with the housing 3 for electrical connection and grounding.

In some embodiments, the second electrostatic protection layer 85 is a continuously extending conductive layer stacked on the display side of the display panel 101, the second electrostatic protection layer 85 has a first grounding connection point a and a second grounding connection point b that are spaced apart, the first grounding connection point a is connected to one of the first electrostatic protection layers, and the second grounding connection point b is connected to another of the first electrostatic protection layers; where a distance between the first grounding connection point a and the second grounding connection point b is less than or equal to 14 mm.

In the embodiment shown in FIG. 12, the second electrostatic protection layer 85 is not segmented and may be provided with multiple spaced grounding connection points, each grounding connection point being grounded through the aforementioned electrostatic discharge path.

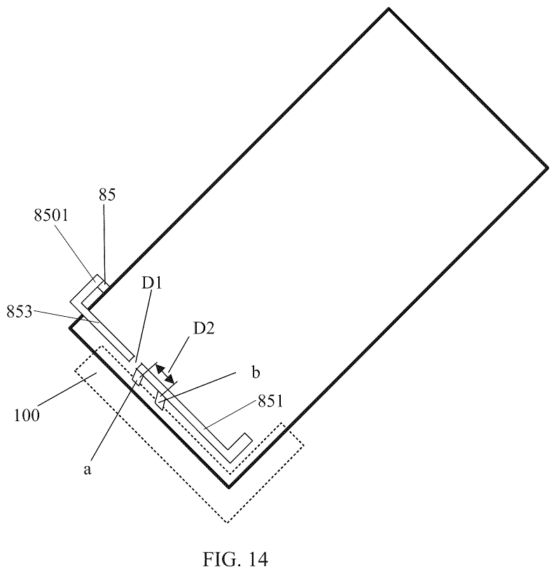

In the embodiment shown in FIG. 14, the second electrostatic protection layer 85 includes a first electrostatic protection segment 851 and a second electrostatic protection segment 853, where a gap D1 is formed between the first electrostatic protection segment 851 and the second electrostatic protection segment 853. The first electrostatic protection segment 851 is a continuously extending segment of the second electrostatic protection layer, and the first electrostatic protection segment 851 may include multiple grounding connection points. To be specific, the first electrostatic protection segment 851 includes a first grounding connection point a and a second grounding connection point b. The first grounding connection point a is connected to one first electrostatic protection layer 81, and the second grounding connection point b is connected to another first electrostatic protection layer 81. A distance D2 between the first grounding connection point a and the second grounding connection point b is less than or equal to 14 mm.

The first electrostatic protection segment 851 is connected to two first electrostatic protection layers 81, so that the same second electrostatic protection layer can form corresponding electrostatic discharge paths of the capacitive structure C at the first grounding connection point a and the second grounding connection point b. Thus, static electricity discharged to the second electrostatic protection layer of the electronic device can be grounded through multiple electrostatic discharge paths of the capacitive structure C, discharging the static electricity to the housing 3 and achieving electrostatic coupling discharge. This not only meets electrostatic protection requirements but also minimizes the impact on the antenna.

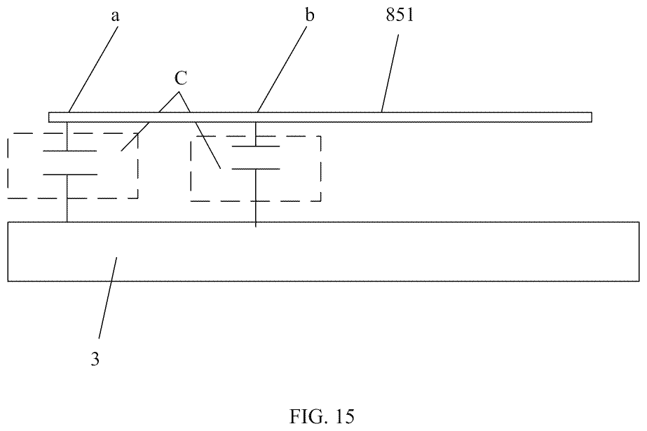

If the first electrostatic protection segment 851 is located within the antenna arrangement region 100, the distance D2 between the first grounding connection point a and the second grounding connection point b of the first electrostatic protection segment 851 should not be too large, especially not at the two ends of the first electrostatic protection segment 851. As shown in FIG. 15, the first grounding connection point a and the second grounding connection point b on the same first electrostatic protection segment 851 each form a capacitive structure C, equivalent to two capacitive structures C in parallel. An equivalent capacitance formed at the end of the first electrostatic protection segment 851 is larger, which consequently leads to a significantly increased equivalent electrical length of the first electrostatic protection segment 851, and the spurious frequency generated by the first electrostatic protection segment 851 is likely to fall within the operating frequency band of the antenna, affecting antenna performance. For example, if the length of the first electrostatic protection segment 851 is 20 mm, spurious emissions generated occur at frequencies above 2.9 GHZ. Therefore, the distance D2 between the first grounding connection point a and the second grounding connection point b should not be too large and needs to be less than or equal to 14 mm, which is the minimum resonant length for the highest frequency (for example, B41), thereby preventing spurious emissions generated by the first electrostatic protection layer from falling into the highest frequency band.

In some embodiments, the electronic device further includes an antenna arrangement region 100 provided with an antenna, where the second electrostatic protection layer 85 is a continuous conductive layer stacked on the display side of the display panel 101, at least a portion of the second electrostatic protection layer 85 is stacked opposite the antenna arrangement region 100, a first end of the second electrostatic protection layer 85 is grounded and located outside the antenna arrangement region 100, and a second end of the second electrostatic protection layer 85 away from the first end is located within the antenna arrangement region 100; and the capacitive structure is disposed between the first end and the second end of the second electrostatic protection layer 85, and the first electrostatic protection layer is connected between the first end and the second end of the second electrostatic protection layer 85.

In this embodiment, the second electrostatic protection layer 85 is a single continuously extending electrostatic protection layer, and the first end and the second end are two ends of a corresponding branch of the electrostatic protection layer, one end being located within the antenna arrangement region 100 and another end being located outside the antenna arrangement region 100.

As shown in FIG. 12, the end 8501 of the second electrostatic protection layer 85 is located outside the antenna arrangement region and is grounded, another end 8503 of the second electrostatic protection layer 85 far away from the end 8501 is located within the antenna arrangement region 100, and at least a portion of the second electrostatic protection layer 85 is stacked opposite the antenna arrangement region 100. The end 8501 of the second electrostatic protection layer 85 is in direct contact with the housing 3 for grounding, allowing static electricity to be conductively discharged to the housing 3.

The capacitive structure is disposed between the end 8501 and the end 8503 of the second electrostatic protection layer 85, that is, the first electrostatic protection layer is connected to the second electrostatic protection layer at positions other than the end 8501 and the end 8503.

The implementation of direct conductive electrostatic discharge by directly grounding the end 8501 of the second electrostatic protection layer 85 located outside the antenna arrangement region through a direct conductive path can provide good electrostatic protection for the display screen 1. However, single-ended grounding of the second electrostatic protection layer 85 can respond to odd harmonic modes excited by the antenna signal. With the length of the second electrostatic protection layer 85 being increased and its fundamental frequency being controlled to be less than the lowest frequency band B28 of low-frequency signals without affecting its first channel, the harmonic resonance point can be controlled at 550 MHz. Ideally, the third harmonic frequency excited by the second electrostatic protection layer 85 is at 1650 MHZ, lower than the first channel of B3 (1710 MHz); the fifth harmonic frequency excited by the second electrostatic protection layer 85 is at 2750 MHz, higher than the last channel of B41 (2690 MHZ). However, since the margin is very narrow, actual assembly and mass production process variations can easily cause the third and fifth harmonic spurious frequencies excited by the second electrostatic protection layer 85 to deviate into the operating frequency band of the antenna.

To address this, the capacitive structure of the embodiments of the present application increases the capacitance between the electrostatic protection layer and the housing to control the odd harmonic frequencies excited by the second electrostatic protection layer to fall outside the operating frequency band of antenna signals, ensuring electrostatic protection for the display screen by the second electrostatic protection layer while minimizing its impact on the antenna.

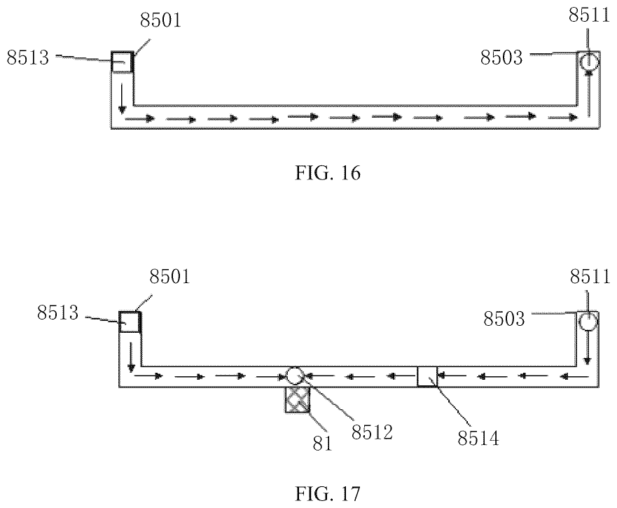

As shown in FIG. 16 to FIG. 18, compared to the current distribution of a fundamental frequency, the current distribution of a third harmonic frequency has one additional electric field hotspot and one additional current hotspot, and the current distribution of a fifth harmonic frequency has two additional electric field hotspots and two additional current hotspots. The end 8501 of the second electrostatic protection layer 85 corresponds to the strongest current point 8513 (represented by a rectangle in the figure), and the end 8503 of the second electrostatic protection layer 85 corresponds to the strongest electric field point 8511 (represented by a circle in the figure).

In one embodiment, in response to an antenna signal, there is at least one electric field hotspot position and at least one current hotspot position between the first end and the second end of the second electrostatic protection layer, and the capacitive structure is disposed at the electric field hotspot position or the current hotspot position.

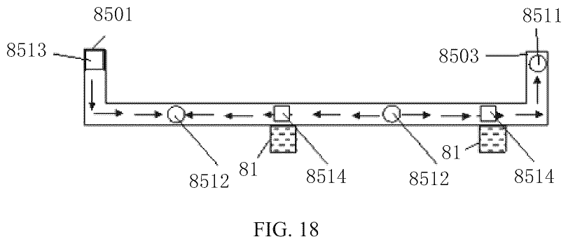

In the embodiments shown in FIG. 17 and FIG. 18, an end 8501 of the second electrostatic protection layer 85 is the first end, and another end 8503 of the second electrostatic protection layer 85 is the second end. In response to an antenna signal, the end 8501 of the second electrostatic protection layer 85 generates a current hotspot 8513, and the end 8503 of the second electrostatic protection layer 85 generates an electric field hotspot 8511. An electric field hotspot 8512 and a current hotspot 8514 are also formed simultaneously between the end 8501 and the end 8503 of the second electrostatic protection layer 85. Thus, the capacitive structure is disposed at the position corresponding to the electric field hotspot 8512 or the current hotspot 8514 between the two ends of the second electrostatic protection layer 85, and the first electrostatic protection layer 81 is connected to the second electrostatic protection layer 85 at the position of the electric field hotspot 8512 or the current hotspot 8514, effectively reducing the impact of the electrostatic protection layer on antenna performance.

At the position of the electric field hotspot 8512 or the current hotspot 8514 between the end 8501 and the end 8503 of the second electrostatic protection layer 85, a segment of the first electrostatic protection layer 81 extends from the second electrostatic protection layer 85 toward the housing 3, and the first electrostatic protection layer 81 forms a parallel plate capacitive structure with the conductive portion disposed on the housing 3 and a dielectric layer, such as an air layer between the first electrostatic protection layer 81 and the conductive portion. When the first electrostatic protection layer 81 is closer to the conductive portion disposed opposite thereto, the parallel overlapping area is larger, the capacitance of the formed capacitive structure is larger, and the loaded capacitance is stronger. Reducing the distance between the first electrostatic protection layer 81 and the conductive portion can increase the capacitance between the second electrostatic protection layer and the housing 3, thereby lowering the resonant frequency of the electrostatic protection layer, controlling the generated spurious frequencies to fall outside the operating frequency band of the antenna, thus maximizing the reduction of its impact on the operating frequency band of the antenna signal while ensuring the electrostatic protection function of the second electrostatic protection layer 85.

In some embodiments, in response to an antenna signal, the second electrostatic protection layer has a first electric field hotspot position and a second electric field hotspot position, the second electric field hotspot position is located at the first end of the second electrostatic protection layer, the first electric field hotspot position is located between the first end and the second end of the second electrostatic protection layer, the capacitive structure is disposed at the first electric field hotspot position, and the first electrostatic protection layer is connected to the first electric field hotspot position.

In the embodiment shown in FIG. 17, for the third harmonic frequency excited by the second electrostatic protection layer 85, in addition to the second electric field hotspot 8511 at the end 8503 of the second electrostatic protection layer, the second electrostatic protection layer 85 also excites a first electric field hotspot 8512 located between the end 8501 and the end 8503 of the second electrostatic protection layer 85.

For the third harmonic frequency excited by the second electrostatic protection layer 85, it is necessary to control the frequency of the third harmonic below 1710 MHz without affecting the first channel of B3. Therefore, connecting the first electrostatic protection layer 81 at the position of the first electric field hotspot 8512 located between the end 8501 and the end 8503 of the second electrostatic protection layer 85 to form a capacitive structure can maximize the reduction of the impact on antenna performance.

In some embodiments, in response to an antenna signal, the second electrostatic protection layer has at least one electric field hotspot position and at least one current hotspot position, and the second end of the second electrostatic protection layer is an electric field hotspot position; and the capacitive structure is disposed at a current hotspot position located between the first end and the second end of the second electrostatic protection layer, and the first electrostatic protection layer is connected to at least one of the current hotspot positions.

In the embodiment shown in FIG. 18, for the fifth harmonic frequency excited by the second electrostatic protection layer 85, in addition to the second electric field hotspot 8511, the first electric field hotspot 8512, and the current hotspot 8513 located at the end 8501 of the second electrostatic protection layer, the second electrostatic protection layer 85 also excites a current hotspot 8514 located between the end 8501 and the end 8503 of the second electrostatic protection layer 85.

For the fifth harmonic frequency excited by the second electrostatic protection layer 85, it is necessary to increase its frequency to avoid falling within the highest frequency band B41, which is the opposite of the approach for the third harmonic embodiment described above. Therefore, connecting the first electrostatic protection layer 81 at the position of the current hotspot 8514 located between the end 8501 and the end 8503 of the second electrostatic protection layer 85 to form a corresponding capacitive structure.

Two current hotspots 8514 exist at positions between the end 8501 and the end 8503 of the second electrostatic protection layer 85. The two current hotspot 8514 positions are each provided with the aforementioned capacitive structure. The second electrostatic protection layer 85 is connected to the first electrostatic protection layer 81 in the capacitive structure at the positions of the two current hotspots 8514. When the first electrostatic protection layer 81 is closer to the conductive portion disposed opposite thereto, the parallel overlapping area is larger, the capacitance of the formed capacitive structure is larger, and the loaded capacitance is stronger. Adding the first electrostatic protection layer 81 to the second electrostatic protection layer reduces the distance to the conductive portion, increasing the capacitance between the electrostatic protection layer and the housing at the strongest current point, thereby increasing the resonant frequency of the fifth harmonic of the electrostatic protection layer, and controlling the spurious frequencies to fall outside the B41 band. This maximizes the reduction of its impact on the operating frequency band of the antenna signal while ensuring the electrostatic protection function of the second electrostatic protection layer 85.

In some embodiments, the electronic device may include a first capacitive structure and a second capacitive structure, where the first capacitive structure is disposed at the first end of the second electrostatic protection layer, the first end of the second electrostatic protection layer is connected to the first electrostatic protection layer in the first capacitive structure, and the first end of the second electrostatic protection layer is grounded through the first capacitive structure; and the second capacitive structure is disposed between the first end and the second end of the second electrostatic protection layer, and the second electrostatic protection layer is connected through the first electrostatic protection layer in the second capacitive structure to increase the capacitance between the second electrostatic protection layer and the housing.

In the embodiments of FIG. 16 to FIG. 18, the end 8501 of the second electrostatic protection layer 85 located outside the antenna arrangement region 100 may be grounded through an electrostatic discharge path. That is, the end 8501 of the second electrostatic protection layer 85 is grounded through the electrostatic discharge path formed through the first capacitive structure, and a portion of the second electrostatic protection layer 85 located between the end 8501 and the another end 8503 of the second electrostatic protection layer 85 increases the capacitance between the second electrostatic protection layer and the housing through the second capacitive structure, thereby reducing the impact on antenna performance.

It can be understood that the second capacitive structure may be disposed at a current hotspot position or an electric field hotspot position depending on the type of antenna signal, and specific details can refer to the relevant descriptions of FIG. 17 and FIG. 18 above, which will not be repeated here.

In this embodiment, increasing the capacitance between the second electrostatic protection layer 85 and the housing 3 by disposing the second capacitive structure between the end 8501 and another end 8503 of the second electrostatic protection layer 85 can reduce the impact of the electrostatic protection layer on the operating frequency band of the antenna signal.

When the second electrostatic protection layer discharges static electricity through the electrostatic discharge path of the first capacitive structure, the second electrostatic protection layer can also cause the even harmonic spurious frequencies excited by the second electrostatic protection layer to fall outside the operating frequency band of the antenna signal through the second capacitive structure.

In an embodiment of the present application, the electronic device includes a display screen, a housing, a first electrostatic protection layer, and a dielectric layer, where the display screen includes a display panel and a wire structure electrically connected to the display panel, the display screen is disposed on one side of the housing, the housing is provided with a conductive portion, a gap is formed between the housing and the display panel, the first electrostatic protection layer is opposite the conductive portion and is conductive, the dielectric layer is disposed between the first electrostatic protection layer and the conductive portion, and the first electrostatic protection layer, the dielectric layer, and the conductive portion form a capacitive structure, which can effectively protect the flex cable of the display screen from static electricity while minimizing the impact of the related electrostatic protection structure on antenna performance.

It should be noted that, in this document, the terms “include,” “comprise,” or any other variants thereof are intended to cover non-exclusive inclusion, such that a process, method, article, or device including a series of elements includes not only those elements but also other elements not explicitly listed, or elements inherent to such a process, method, article, or device. In the absence of further restrictions, an element defined by the phrase “including a . . . ” does not exclude the presence of additional identical elements in the process, method, article, or device that includes the element. Additionally, it should be pointed out that the scope of the methods and devices in the embodiments of the present application is not limited to performing functions in the order shown or discussed, but may also include performing functions in a substantially simultaneous manner or in reverse order depending on the functions involved, for example, the described methods may be performed in an order different from that described, and various steps may be added, omitted, or combined. Furthermore, features described with reference to certain examples may be combined in other examples.

Through the description of the above embodiments, those skilled in the art can clearly understand that the above embodiment methods can be implemented by means of software plus a necessary general hardware platform, and of course, can also be implemented by hardware, but in many cases, the former is a better implementation. Based on this understanding, the technical solution of the present application, in essence or the part that contributes to the prior art, can be embodied in the form of a computer software product, which is stored in a storage medium (such as ROM/RAM, magnetic disk, optical disk) and includes several instructions to enable a terminal (which may be a mobile phone, computer, server, network device, or the like) to execute the methods described in the various embodiments of the present application.

The embodiments of the present application have been described above in conjunction with the accompanying drawings, but the present application is not limited to the specific embodiments described above, which are merely illustrative and not restrictive. Under the enlightenment of the present application, those of ordinary skill in the art can make many forms without departing from the spirit of the present application and the scope protected by the claims, all of which fall within the protection of the present application.

What is claimed is:

1. An electronic device, comprising:
a display screen comprising a display panel and a wire structure electrically connected to the display panel;
a housing, wherein the display screen is disposed on one side of the housing, the housing is provided with a conductive portion, and a gap is formed between the housing and the display panel;
a first electrostatic protection layer opposite the conductive portion, wherein the first electrostatic protection layer is conductive; and
a dielectric layer disposed between the first electrostatic protection layer and the conductive portion, wherein the first electrostatic protection layer, the dielectric layer, and the conductive portion form a capacitive structure.

2. The electronic device according to claim 1, wherein the first electrostatic protection layer, the dielectric layer, and the conductive portion form an electrostatic discharge path for discharging static electricity through the electrostatic discharge path of the capacitive structure.

3. The electronic device according to claim 2, further comprising an antenna arrangement region, wherein the electrostatic discharge path is located in the antenna arrangement region.

4. The electronic device according to claim 1, wherein the dielectric layer comprises an anodized layer disposed on the housing, the anodized layer comprising a first portion of the anodized layer disposed opposite the first electrostatic protection layer and a second portion of the anodized layer offset from the first electrostatic protection layer, and a thickness of the first portion of the anodized layer is less than a thickness of the second portion of the anodized layer.

5. The electronic device according to claim 2, wherein the dielectric layer comprises an anodized layer disposed on the conductive portion, the anodized layer having at least one hole to form the electrostatic discharge path.

6. The electronic device according to claim 1, further comprising a conductive adhesive, wherein the first electrostatic protection layer is fixed to the housing through the conductive adhesive, the conductive adhesive is located between the dielectric layer and the first electrostatic protection layer, and the first electrostatic protection layer, the conductive adhesive, the dielectric layer, and the conductive portion form an electrostatic discharge path.

7. The electronic device according to claim 1, wherein the housing has a bearing surface configured to support the display screen, the bearing surface is provided with a groove, the groove extends along an edge of the display screen, and the first electrostatic protection layer is inserted into the groove; and
the conductive portion and the dielectric layer are disposed opposite the first electrostatic protection layer, and the three together form an electrostatic discharge path of the capacitive structure.

8. The electronic device according to claim 1, wherein the conductive portion is opposite a side of the display panel, the gap is formed between the conductive portion and the display panel, one end of the first electrostatic protection layer is located within the gap, and another end of the first electrostatic protection layer extends toward an opening of the gap and protrudes from the display screen or the housing.

9. The electronic device according to claim 2, wherein the dielectric layer is an air layer, one side of the conductive portion is fixed within the gap, and another side of the conductive portion extends toward an opening of the gap; and
the first electrostatic protection layer is stacked directly above the conductive portion and separated from the conductive portion to form a spacing to accommodate the dielectric layer.

10. The electronic device according to claim 9, wherein the housing is provided with a groove, the groove extends around the display screen, the conductive portion is fixed to the groove via a conductive adhesive, an end face of the conductive portion facing away from the groove and the first electrostatic protection layer are disposed opposite each other and form the spacing, and the first electrostatic protection layer is disposed on a display side of the display panel.

11. The electronic device according to claim 10, wherein an end face of the conductive portion facing away from the groove and the first electrostatic protection layer are disposed opposite each other and form the spacing, the end face of the conductive portion facing away from the groove has a first protrusion structure; and a second protrusion structure, matching the first protrusion structure, is provided on a side of the first electrostatic protection layer facing the conductive portion,
wherein the first protrusion structure, the second protrusion structure, and the dielectric layer located between the first protrusion structure and the second protrusion structure form the electrostatic discharge path.

12. The electronic device according to claim 9, further comprising a decorative member, wherein the decorative member has a first decorative portion stacked on a display side of the display screen and a second decorative portion inserted into the gap, the first decorative portion and the second decorative portion being connected; and
the first electrostatic protection layer is disposed on the first decorative portion, and the conductive portion is disposed on the second decorative portion.

13. The electronic device according to claim 1, further comprising a second electrostatic protection layer, wherein the second electrostatic protection layer is connected to the first electrostatic protection layer and extends to a display side of the display panel;
and the housing has a grounding path, and the second electrostatic protection layer is in direct contact with the housing for grounding.

14. The electronic device according to claim 2, further comprising a second electrostatic protection layer, wherein the second electrostatic protection layer is connected to the first electrostatic protection layer and extends to a display side of the display panel, the first electrostatic protection layer is disposed in the gap between the housing and the display panel, and the second electrostatic protection layer is grounded through the electrostatic discharge path.

15. The electronic device according to claim 14, wherein the second electrostatic protection layer extends around an edge of an end of the display panel near the wire structure, and the first electrostatic protection layer is disposed at an end of the second electrostatic protection layer far away from the wire structure to form a grounding connection point.

16. The electronic device according to claim 14, further comprising a decorative member, wherein the decorative member has a first decorative portion stacked on the display side of the display screen and a second decorative portion inserted into the gap, the first decorative portion and the second decorative portion being connected; and
the first electrostatic protection layer is disposed on the second decorative portion, and the second electrostatic protection layer is disposed on the first decorative portion.

17. The electronic device according to claim 14, further comprising an antenna arrangement region; wherein
the second electrostatic protection layer comprises a first electrostatic protection segment and a second electrostatic protection segment, wherein the first electrostatic protection segment and the second electrostatic protection segment are separated and spaced apart, and the first electrostatic protection segment has a first grounding connection point, the first grounding connection point being located within the antenna arrangement region; and the second electrostatic protection segment has a second grounding connection point, the second grounding connection point being located outside the antenna arrangement region;
the first electrostatic protection layer is connected to the first grounding connection point of the first electrostatic protection segment, and the first grounding connection point is grounded through the electrostatic discharge path; and
the second grounding connection point of the second electrostatic protection segment is in direct contact with the housing for conduction and is grounded through a grounding path of the housing.

18. The electronic device according to claim 17, wherein the first electrostatic protection segment and the second electrostatic protection segment are separated to form a gap, the gap being opposite the wire structure; and
a minimum distance between a plane of the second electrostatic protection layer and the wire structure is greater than or equal to twice a width of the gap.

19. The electronic device according to claim 14, wherein the second electrostatic protection layer is connected to multiple first electrostatic protection layers so as to be grounded through multiple electrostatic discharge paths,
wherein the electronic device further comprises:
an antenna arrangement region; wherein the second electrostatic protection layer comprises a first electrostatic protection segment and a second electrostatic protection segment located within the antenna arrangement region, the first electrostatic protection segment and the second electrostatic protection segment are separated and spaced apart, the first electrostatic protection segment has a first grounding connection point, and the second electrostatic protection segment has a second grounding connection point; and
the first grounding connection point of the first electrostatic protection segment is connected to one of the first electrostatic protection layers, causing the first electrostatic protection segment to be grounded through a first electrostatic discharge path; and the second grounding connection point of the second electrostatic protection segment is connected to another of the first electrostatic protection layers, causing the second electrostatic protection segment to be grounded through a second electrostatic discharge path.

20. The electronic device according to claim 13, further comprising an antenna arrangement region provided with an antenna, wherein the second electrostatic protection layer is a continuous conductive layer stacked on the display side of the display panel, at least a portion of the second electrostatic protection layer is stacked opposite the antenna arrangement region, a first end of the second electrostatic protection layer is grounded and located outside the antenna arrangement region, and a second end of the second electrostatic protection layer away from the first end is located within the antenna arrangement region; and
the capacitive structure is disposed between the first end and the second end of the second electrostatic protection layer, and the first electrostatic protection layer is connected between the first end and the second end of the second electrostatic protection layer.
